(19) United States
(12) Patent Application Publication
(10) Pub. No.: US 2025/0293061 A1
(43) Pub. Date: Sep. 18, 2025

(54) SEMICONDUCTOR PROCESS EQUIPMENT

(71) Applicant: Samsung Electronics Co., Ltd., Suwon-si (KR)

(72) Inventors: Jonghwa Kim, Suwon-si (KR); Yunha Kim, Suwon-si (KR); Sangsu Yeh, Suwon-si (KR); Minsu Lee, Suwon-si (KR); Yunkyun Lee, Suwon-si (KR); Jiae Jung, Suwon-si (KR); Kwanghyun Cho, Suwon-si (KR); Hansung Cho, Suwon-si (KR)

(21) Appl. No.: 19/001,069

(22) Filed: Dec. 24, 2024

(30) Foreign Application Priority Data
Mar. 18, 2024 (KR) 10-2024-0037041

(51) Int. Cl. H01L 21/67; G05B 19/418

(52) U.S. Cl. CPC H01L 21/67253; G05B 19/41875; G05B 2219/45031

(57) ABSTRACT

Semiconductor process equipment includes a wafer support with a wafer including a plurality of support areas, and a processor receiving measurement data obtained from measurement areas defined on the wafer on which a semiconductor process has been performed based on current control data, calculate representative data for each measurement area from the measurement data, calculate error data by calculating a difference between the representative data and predetermined target data, determine, in response to the error data falling within a predetermined range, the current control data as final control data, and, in response to the error data being out of the predetermined range, generate correction data based on a response matrix defining a relationship between the correction data and the error data and adjust the current control data with the correction data to generate a modified control data.

CROSS-REFERENCE TO RELATED APPLICATION(S)

This application claims the benefit under 35 USC 119 (a) of Korean Patent Application No. 10-2024-0037041 filed on Mar. 18, 2024 in the Korean Intellectual Property Office, the entire disclosure of which is herein incorporated by reference for all purposes.

### BACKGROUND

The present inventive concept relates to semiconductor process equipment.

Semiconductor processes such as deposition and etching using plasma may be performed in semiconductor process equipment. After a semiconductor process is undertaken, it may be desirable to measure uniform process results on a wafer. Semiconductor processes may be controlled by control data, and process results may be determined from measurement data obtained by measuring a wafer. Before performing a semiconductor process, semiconductor process equipment may determine final control data to produce uniform process results on the wafer. At this time, the final control data can now be determined by adjusting the control data based on the measurement data obtained from the wafer that has undergone the semiconductor process.

### SUMMARY

Example embodiments provide a semiconductor process equipment in which a response matrix representing relationships between control data and measurement data may be calculated before performing a semiconductor process, and final control data may be reflected by determining the final control data using the response matrix to perform the semiconductor process, thereby controlling process results to be uniform.

According to an aspect of the present disclosure, semiconductor process equipment includes a wafer support with a wafer seated thereon and including a plurality of support areas, and a processor configured to receive measurement data obtained from a plurality of measurement areas defined on the wafer on which a semiconductor process has been performed based on current control data for each of the plurality of support areas controlling the semiconductor process, calculate representative data for each of the plurality of measurement areas from the measurement data, calculate error data by calculating a difference between the representative data and predetermined target data, determine, in response to the error data falling within a predetermined range, the current control data as final control data, and, in response to the error data being out of the predetermined range, generate correction data for each of the plurality of support areas based on a response matrix defining a relationship between the correction data correcting the current control data for each of the plurality of support areas and the error data of the plurality of measurement areas and adjust the current control data with the correction data to generate a modified control data.

According to an aspect of the present disclosure, semiconductor process equipment includes a wafer support with a wafer seated thereon and including a plurality of support areas, and a processor configured to receive measurement data obtained from a plurality of measurement areas defined on the wafer on which a semiconductor process has been performed based on current control data for each of the plurality of support areas controlling the semiconductor process, calculate representative data for each of the plurality of measurement areas from the measurement data by calculating a weighted average of the measurement data obtained from each of the plurality of measurement areas, calculate error data by calculating a difference between the representative data and predetermined target data, determine, in response to the error data falling within a predetermined range, the current control data as final control data, and, in response to the error data being out of the predetermined range, generate correction data for each of the plurality of support areas based on a response matrix defining a relationship between the correction data correcting the current control data for each of the plurality of support areas and the error data of the plurality of measurement areas and adjust the current control data with the correction data to generate a modified control data.

According to an aspect of the present disclosure, semiconductor process equipment includes a wafer support with a wafer seated thereon and including a plurality of support areas, and a processor configured to receive measurement data obtained from a plurality of measurement areas defined on the wafer on which a semiconductor process has been performed based on current control data for each of the plurality of support areas controlling the semiconductor process, wherein the plurality of measurement areas correspond to the plurality of support areas, and each of the plurality of measurement areas includes a plurality of sub-areas, and one sub-area of the plurality of sub-areas is disposed to be surrounded by remaining sub-areas of the plurality of sub-areas, calculate representative data for each of the plurality of measurement areas by performing a weighted average of the measurement data obtained from each of the plurality of measurement areas, calculate error data by calculating a difference between the representative data and predetermined target data, determine, in response to the error data falling within a predetermined range, the current control data as final control data; and in response to the error data being out of the predetermined range, generate correction data for each of the plurality of support areas based on a response matrix defining a relationship between the correction data correcting the current control data for each of the plurality of support areas and the error data of the plurality of measurement areas and adjust the current control data with the correction data to generate a modified control data.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a system according to example embodiments;

FIG. 2 is a diagram simply illustrating a semiconductor processing system according to example embodiments;

FIG. 3 is a diagram simply illustrating semiconductor process equipment according to example embodiments;

FIG. 4 is a diagram simply illustrating semiconductor process equipment and a measurement apparatus according to example embodiments;

FIG. 5 is a flowchart illustrating a process of determining final control data according to example embodiments;

FIG. 6 is a diagram simply illustrating a plurality of support areas according to example embodiments;

FIG. 7 is a diagram illustrating a response matrix according to example embodiments;

FIG. 8 is a flowchart illustrating a process of calculating a response matrix according to example embodiments;

FIGS. 9 and 10 are diagrams simply illustrating a plurality of sub-areas according to example embodiments;

FIG. 11 is a diagram illustrating a response matrix according to example embodiments;

FIGS. 12A and 12 are diagrams illustrating a measurement area according to example embodiments;

FIG. 13 is a diagram illustrating a measurement area according to example embodiments;

FIG. 14 is a diagram illustrating weights according to example embodiments; and

FIGS. 15A to 15C are diagrams illustrating error data calculated from semiconductor process equipment according to example embodiments.

### DETAILED DESCRIPTION

Hereinafter, example embodiments will be described with reference to the accompanying drawings.

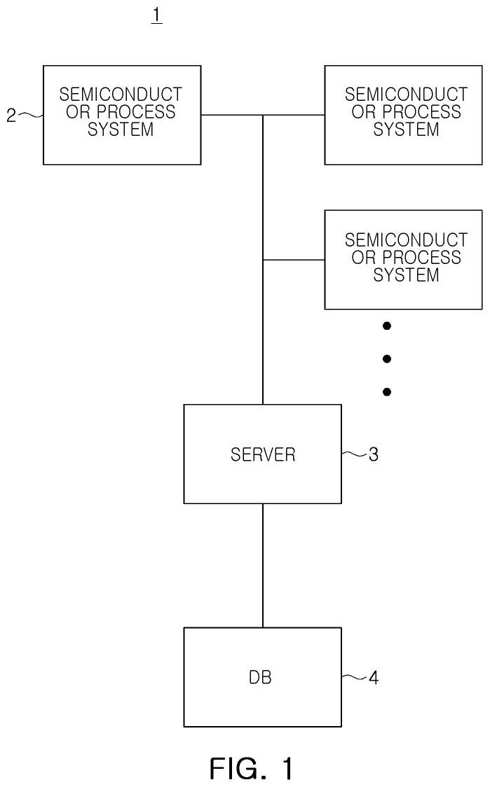

FIG. 1 is a diagram illustrating a system according to example embodiments.

Referring to FIG. 1, a system 1 may include at least one semiconductor processing system 2, a server 3, and a data base (DB) 4. The system 1 according to example embodiments may determine final control data for controlling the semiconductor process before performing the semiconductor process in the semiconductor processing system 2. The system 1 may operate semiconductor process equipment by reflecting the determined final control data and control the process results on the wafer to be uniform.

In example embodiments, the semiconductor processing system 2 may include a wafer support and a processor. A wafer may be seated on the wafer support and a semiconductor process may be performed on the wafer, and the wafer support may include a plurality of support areas. The processor may control the wafer support and the processor. Additionally, the processor may receive measurement data obtained from a plurality of measurement areas defined on a wafer on which a semiconductor process has been performed, and may determine control data for each of a plurality of support areas controlling the semiconductor process.

In example embodiments, the temperature of the wafer may be an important control factor (i.e., a process control parameter) affecting the results of a process such as an etching process or the like performed on the wafer. The wafer support may include a heater thermally controlling a temperature of the wafer. The processor may control the temperature of the wafer using a heater.

Since the wafer support includes gas holes, lift pin holes, heaters, and the like, the internal structure of the wafer support may not be uniform. Due to the non-uniform internal structure of the wafer support, temperature differences may also occur in the wafer depending on regions of the wafer. Some areas of the wafer may have relatively high or low temperatures. Due to such temperature differences between regions of the wafer, non-uniform process results may appear in the regions of the wafer, and the results and yield of the semiconductor process may deteriorate.

The temperature for each of the plurality of support areas may be individually controlled, which may reduce the temperature difference between regions of the wafer. Accordingly, uniform process results may be obtained among regions of the wafer. In detail, the processor may determine control data (i.e., values of the process control parameter) for each of the plurality of support areas and control the process results on the wafer to be uniform.

At this time, the process results on the wafer may be determined by measurement data obtained by measuring a wafer on which a semiconductor process has been performed based on the control data. In example embodiments, the control data may include specific values of the temperature of the heater. Process results on the wafer may include temperature of a wafer or a pattern size (e.g., critical dimension (CD)) of patterns formed on the wafer. In an embodiment, the control data may represent values of process control parameters such as the temperature of the heater. For example, the process control parameters of a semiconductor process may vary depending on fabrication processes and may be variables that are monitored and controlled to ensure desired process results. The process results on the wafer may include temperatures of a wafer or a pattern size (e.g., critical dimension (CD)) of a pattern formed on the wafer. The process results may correspond to values of monitoring parameters (e.g., the CD) of a processed wafer based on the process control parameters. In an etching process for patterning gate lines, the process control parameters may include a temperature of a heater, a gas flow rate, a plasma power, a substrate bias power, or a chamber pressure. The control data may correspond to values of the process control parameters applied in the etching process. For the temperature of a heater as the process control parameter, the control data may include specific temperature values of the heater applied in the etching process. After completing the etching process, the impact of the process control parameters can be monitored or evaluated by measuring the values of the monitoring parameters. In the etching process of patterning gate electrodes, a process control parameter may include a temperature of a heater, and the control data may include a specific value of the temperature applied in the etching process. After completing the etching process, the monitoring parameters may include the CD of each of the gate electrodes patterned in the etching process, and the process results may include specific values of the CD measured using Scanning Electron Microscopy (SEM) equipment, which may be referred to as measurement data. However, the present inventive concept may not be limited thereto.

A general semiconductor processing system may modify control data by incorporating feedback from measurement data obtained from a wafer on which a semiconductor process has been performed. At this time, the control data may be modified based on a predetermined response coefficient that represents the relationship between control data and measurement data.

The predetermined response coefficient may reflect the amount of change in the process result of one measurement area corresponding to each of the plurality of support areas. The predetermined response coefficient may not reflect the amount of change in the process results of the plurality of measurement areas with respect to the control data for each of the plurality of support areas. For example, when each support area has multiple measurement areas, the predetermined response coefficient may not represent the correlation between the measurement data of multiple measurement areas in each support area and the control data of each support area. Accordingly, when modifying control data, the number of modifications may increase due to low accuracy.

The semiconductor processing system 2 according to example embodiments may modify control data based on a response matrix that reflects the amount of change in process results of a plurality of measurement areas with respect to control data for each of a plurality of support areas. Therefore, when modifying control data, accuracy may be improved and the number of modifications may be reduced.

According to example embodiments, data generated and calculated in the semiconductor processing system 2 may be transmitted to the server 3. At this time, the data may include measurement data, control data, and the like. The server 3 may transmit data received from the semiconductor processing system 2 to the DB 4. The DB 4 may store data received from the server 3 and may transmit data requested by the server 3 to the server 3.

The system 1 according to example embodiments may improve the results of the semiconductor process and improve the yield by controlling the process results on the wafer to be uniform by modifying the control data using a response matrix.

In an embodiment of the present inventive concept, as a result of performing the next process on a wafer with uniform process results, the process results on the wafer in a specific measurement area may not be uniformly controlled. Therefore, in a previous semiconductor process, the system 10 may control an offset so as to be applied to control data of a specific measurement area. Accordingly, the system 10 may control the process results of the next process on the wafer to be uniform using the modified control data.

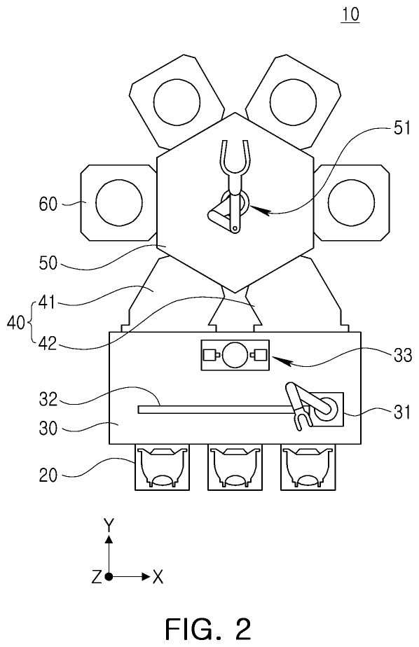

FIG. 2 is a diagram schematically illustrating a semiconductor processing system according to example embodiments.

Referring to FIG. 2, the semiconductor processing system 10 according to an example embodiment may include a wafer transfer device 30, a load lock chamber 40, a transfer chamber 50, a plurality of pieces of semiconductor process equipment 60, and the like. For example, the wafer transfer device 30 may receive wafers through a container such as a Front Opening Unified Pod (FOUP) 20 inside the line where the semiconductor processing system 10 is installed. The wafer transfer device 30 may transfer the wafer received through the FOUP 20 to the load lock chamber 40, or may receive wafers in which semiconductor processing has been completed in the plurality of pieces of semiconductor process equipment 60, from the load lock chamber 40, to be stored in the FOUP 20.

The wafer transfer device 30 may include a wafer transfer robot 31 having an arm capable of holding a wafer, a rail unit 32 for moving the wafer transfer robot 31, an aligner 33 for aligning the wafer, and the like. Assuming an operation of transferring a wafer from the FOUP 20 to the load lock chamber 40, the wafer transfer robot 31 may take out the wafer stored in the FOUP 20 and place the wafer on the aligner 33. The aligner 33 may rotate the wafer to align the wafer in a predetermined direction. When wafer alignment is completed in the aligner 33, the wafer transfer robot 31 may take the wafer out of the aligner 33 and transfer the wafer to the load lock chamber 40.

The load lock chamber 40 is connected to the wafer transfer device 30, and may include a loading chamber 41 where wafers brought into the plurality of pieces of semiconductor process equipment 60 to proceed with the semiconductor process temporarily reside, and an unloading chamber 42 where wafers that are transported out of the plurality of pieces of semiconductor process equipment 60 upon completion of the process temporarily reside. When the wafer aligned in the aligner 33 is brought into the loading chamber 41, the inside of the loading chamber 41 is depressurized to prevent external contaminants from entering.

The load lock chamber 40 may be connected to the transfer chamber 50, and the plurality of pieces of semiconductor process equipment 60 may be connected to the transfer chamber 50 and arranged around the transfer chamber 50. A wafer transfer robot 51 may be placed inside the transfer chamber 50 to transfer wafers between the load lock chamber 40 and the plurality of pieces of semiconductor process equipment 60. The wafer transfer robot 31 of the wafer transfer device 30 may be referred to as a first wafer transfer robot, and the wafer transfer robot 51 of the transfer chamber 50 may be referred to as a second wafer transfer robot.

Each of the plurality of pieces of semiconductor process equipment 60 may perform a semiconductor process on a wafer. For example, a semiconductor process performed by the plurality of pieces of semiconductor process equipment 60 may include a deposition process, an etching process, an exposure process, an annealing process, a polishing process, an ion implantation process, and the like. To perform at least some of the above-mentioned semiconductor processes, plasma may be formed inside at least one of the plurality of pieces of semiconductor process equipment 60.

Plasma may be formed on masks of wafers, substrates for display devices, or the like, which are objects of semiconductor processing. Process results using plasma may be controlled according to control data of semiconductor process equipment 60. Semiconductor process equipment 60 according to example embodiments may control the control data so that the process results on the wafer are uniform.

The semiconductor processing system 10 according to example embodiments may further include a wafer support and a processor. A wafer may be seated on the wafer support to perform a semiconductor process, and the wafer support may include a plurality of support areas. The processor may receive measurement data obtained from a plurality of measurement areas defined on a wafer on which a semiconductor process has been performed, and may determine control data for each of a plurality of support areas controlling the semiconductor process.

The processor may calculate representative data for each of the plurality of measurement areas from the measurement data, and calculate error data by calculating a difference between the representative data and predetermined target data. Additionally, the processor may correct the control data by generating correction data for each of the plurality of support areas based on a response matrix that defines the relationship between correction data and error data for correcting the control data for each of the plurality of support areas.

The processor may determine final control data using correction data whose error data is within a predetermined target range. In detail, calculation of error data and correction of control data may be repeated until the error data falls within a predetermined target range. The processor may determine the corrected control data when the error data is within a predetermined target range as the final control data.

In example embodiments, final control data for each of the plurality of pieces of semiconductor process equipment 60 may be determined. The processor may operate the plurality of pieces of semiconductor process equipment 60 by reflecting the calculated final control data.

The semiconductor processing system 10 according to example embodiments may determine the final control data using only measurement data obtained from the plurality of measurement areas without generating virtual data (i.e., without using interpolation or extrapolation). Accordingly, the accuracy of correction data may be improved, and the number of times control data is modified may be reduced.

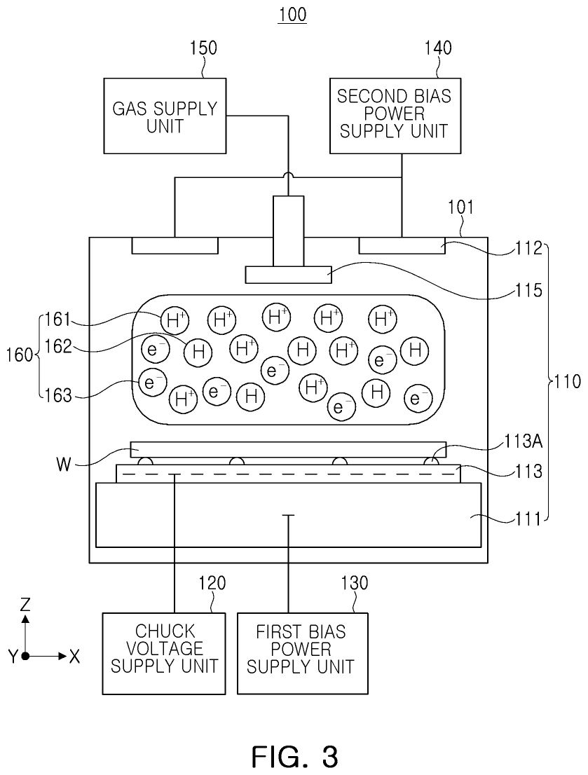

FIG. 3 is a diagram simply illustrating semiconductor process equipment according to example embodiments.

Semiconductor process equipment 100 according to example embodiments may be equipment that performs a semiconductor process using plasma. The semiconductor process equipment 100 may include a chamber 110, a chuck voltage supply unit 120, a first bias power supply unit 130, a second bias power supply unit 140, a gas supply unit 150, and the like.

The chamber 110 may include a housing 101, a first bias electrode 111, a second bias electrode 112, a wafer support 113, a gas flow path 115, and the like. A semiconductor process object on which a semiconductor process will be performed may be seated on the wafer support 113. Additionally, the wafer support 113 may include a heater that heats the semiconductor processing object, and the heater may maintain the temperature of the semiconductor processing object within a certain range. In an example embodiment illustrated in FIG. 3, the semiconductor process object is illustrated as a wafer W, but objects of the semiconductor processing may be changed to a substrate for a display device, a mask, and the like.

In example embodiments, the wafer support 113 may correspond to an electrostatic chuck (ESC). A plurality of protrusions 113A having a protrusion shape may be formed on the upper surface of the wafer support 113. The wafer W is seated on the protrusion 113A, and thus a space may be formed between the upper surface of the wafer support 113 and the wafer W. For example, the space between the upper surface of the wafer support 113 and the wafer W may be filled with helium gas or the like for cooling the wafer W heated by bombardments of ions in the plasma.

The wafer W may be held on the wafer support 113 by the Coulomb force generated from the chuck voltage supplied to the wafer support 113 by the chuck voltage supply unit 120. For example, the chuck voltage supply unit 120 may supply chuck voltage to the wafer support 113 in the form of a constant voltage, and the chuck voltage may have a magnitude of hundreds to thousands of volts.

In an embodiment different from that of FIG. 3, the wafer W may be seated on a vacuum chuck or secured by a non-ESC based support unit. The non-ESC based support unit may secure the wafer W to the non-ESC based support unit using mechanical clamping, vacuum based clamping, or the like. However, the present inventive concept may not be limited thereto.

Plasma gas may flow in through the gas flow path 115 to proceed with the semiconductor process. The first bias power supply unit 130 may supply first bias power to the first bias electrode 111 located below the wafer support 113, and the second bias power supply unit 140 may supply second bias power to the second bias electrode 112 located on the upper part of the wafer support 113. Each of the first bias power supply unit 130 and the second bias power supply unit 140 may include a radio frequency (RF) power source for supplying bias power.

A plasma 160 containing ions 161, radicals 162, electrons 163 and the like is generated in the space above the wafer W by the first bias power and the second bias power, and the reaction gas may be activated by the plasma 160 to increase reactivity. For example, when the semiconductor process equipment 100 is an etching device, the ions 161 of the reaction gas may be accelerated toward the wafer W by the first bias power supplied by the first bias power supply unit 130 to the first bias electrode 111. At least some of the semiconductor substrates or layers included in the wafer W may be dry-etched by the ions 161 and the radicals 162 of the reaction gas.

In example embodiments, before performing a semiconductor process using the plasma 160, final control data may be determined using a response matrix. A semiconductor process equipment 100 may be operated by reflecting the determined final control data. By producing uniform process results on the wafer, the reliability and yield of the semiconductor process may be improved.

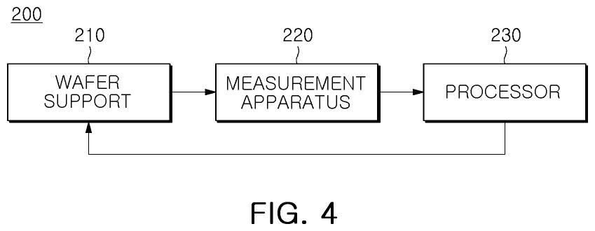

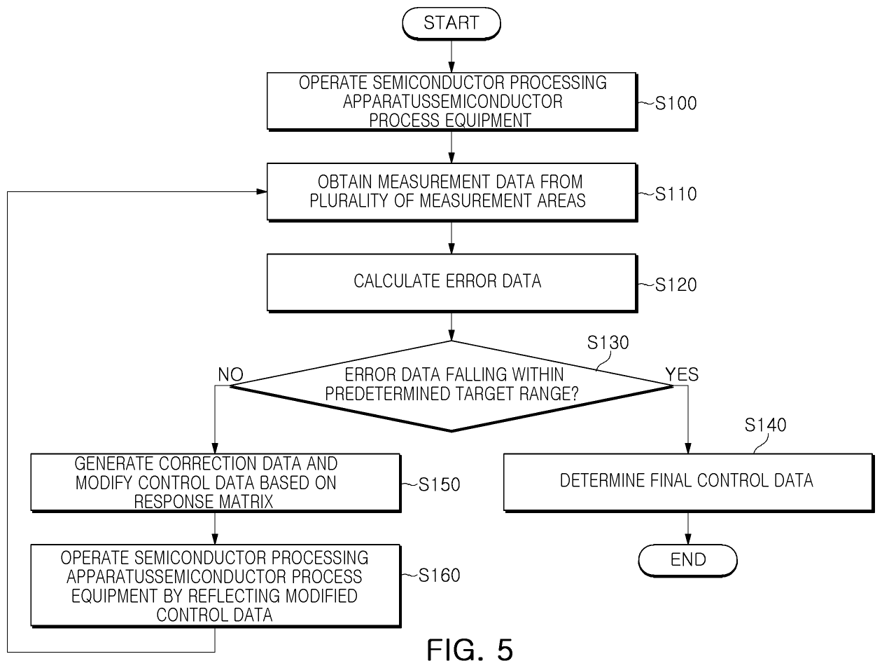

FIG. 4 is a diagram simply illustrating a semiconductor process equipment and a measurement apparatus according to example embodiments. FIG. 5 is a flowchart illustrating the process of determining final control data according to example embodiments.

First, referring to FIG. 4, semiconductor process equipment may include a wafer support 210, a processor 230, and the like. The wafer support 210 may include a plurality of support areas. The processor 230 may control the wafer support 210. Specific embodiments of semiconductor process equipment may be similar to those previously described in FIGS. 1 to 3.

The measurement apparatus 220 may obtain measurement data by measuring a wafer on which a semiconductor process has been performed. The measurement apparatus 220 may measure a wafer seated inside a semiconductor process equipment. The present disclosure is not limited thereto. In an embodiment, the measurement apparatus 220 may receive a wafer from a semiconductor process equipment through a container such as a FOUP or the like and measure the wafer outside the semiconductor process equipment. The measurement apparatus 220 may include, but may not be limited to, Scanning Electron Microscope (SEM) equipment.

Measurement data may include pattern size, wafer temperature, End Point Detection (EPD) timing, or the like. The measurement data may vary according to a kind of a fabrication process to be monitored. For example, when a fabrication process to be monitored is an etching process of patterning gate lines, the measurement data may be a pattern size (e.g., a width of a gate line patterned) and a spacing between two adjacent patterns. The measurement apparatus 220 may transmit the acquired measurement data to the processor 230. Additionally, the measurement data may be transmitted and stored in the DB 4 in FIG. 1.

The processor 230 may determine control data for each of a plurality of support areas controlling a semiconductor process. The control data may include the temperature of the heater included in the wafer support 210, but is not limited thereto, and may include the pressure of the plasma gas, the flow rate of the plasma gas, bias power, or the like.

Referring to FIGS. 4 and 5, after the wafer is placed on the wafer support 210, the processor 230 may operate a semiconductor process equipment (S100). The processor 230 operates the semiconductor process equipment by reflecting the control data for each of the plurality of support areas, so that the semiconductor process of which process conditions are set by the control data may be performed on the wafer.

After the semiconductor process for the wafer is completed, the measurement apparatus 220 may measure the wafer and obtain measurement data from a plurality of measurement areas defined on the wafer (S110). The measurement apparatus 220 may transmit the acquired measurement data to the processor 230.

The processor 230 may calculate error data for each of the plurality of measurement areas using the received measurement data (S120). For example, the processor 230 may calculate representative data for each of a plurality of measurement areas from the measurement data and calculate error data by calculating the difference between the representative data and predetermined target data. For example, when multiple measurements are performed in each of the plurality of measurement areas, measurement data of each measurement area may be represented by the representative data. The representative data may be obtained by averaging values of the multiple measurements or by applying weight values to the multiple measurements, which will be described later.

Predetermined target data may be specific measurement data for a plurality of measurement areas. Predetermined target data may differ depending on the semiconductor process and/or measurement data. As measurement data for a plurality of measurement areas converges to predetermined target data, the results of the semiconductor process for the wafer may be improved.

The processor 230 may determine whether the error data falls within a predetermined target range (S130). The predetermined target range may correspond to a certain range of predetermined target data. When the error data falls within the predetermined target range (YES in S130), the processor 230 may determine final control data (S140). The final control data may be control data applied to a semiconductor process to be performed in the semiconductor process equipment. For example, the final control data may correspond to values of the process control parameters to be applied to a semiconductor process of the semiconductor process equipment.

When the error data does not fall within the predetermined target range (i.e., are out of the predetermined target range) (NO in S130), the processor 230 may proceed to steps S150 an S160 without determining the current control data as the final control data (S150 and S160). First, the processor 230 may generate correction data based on the response matrix and modify control data using the correction data (S150). In detail, the processor 230 may generate correction data for each of a plurality of support areas based on a response matrix that defines the relationship between the error data and the correction data correcting the control data for each of the plurality of support areas. In an embodiment, the correction data may be applied to the control data, thereby modifying or adjusting the control data to generate new modified control data to be applied in step S160.

The processor 230 may operate a semiconductor process equipment by reflecting the modified control data (S160). Thereafter, the process of the processor 230 acquiring measurement data, calculating error data, and determining whether the error data falls within a predetermined target range may be repeated (S110 to S130). By repeating the above processes, the processor 230 may determine the corrected control data when the error data is within a predetermined target range as the final control data.

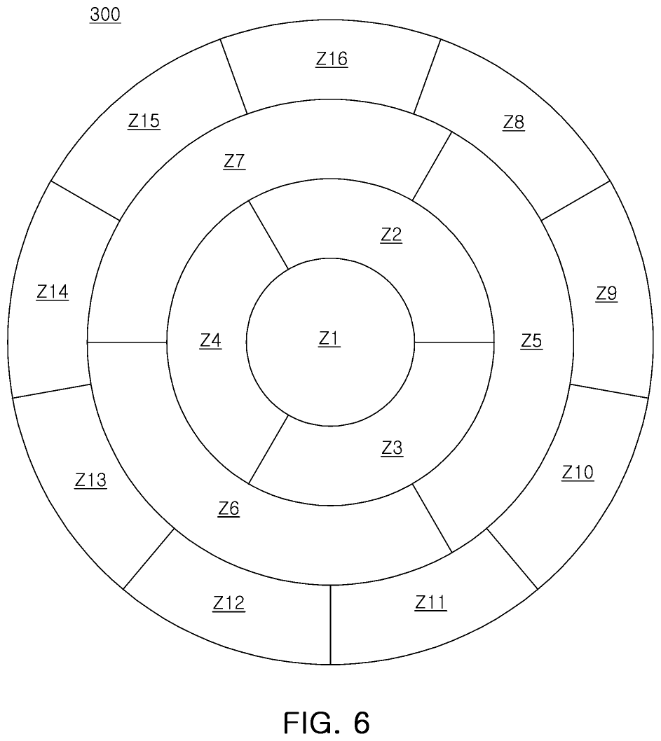

FIG. 6 is a diagram simply illustrating a plurality of support areas according to example embodiments.

A semiconductor process equipment according to example embodiments may include a wafer support 300. A wafer is seated on the wafer support and a semiconductor process may be performed. Specific embodiments of a semiconductor process equipment and wafer support 300 may be similar to those previously described in FIGS. 1 to 5.

The wafer support 300 may include a plurality of support areas. A semiconductor process equipment may determine control data for each of a plurality of support areas and control the process results on the wafer to be uniform.

FIG. 6 may illustrate the upper surface of the wafer support 300 according to example embodiments, and the upper surface of the wafer support 300 may be circular. The wafer support 300 may include, but is not limited to, first to sixteenth support areas Z1 to Z16.

The plurality of support areas Z1 to Z16 may be discriminated by at least one concentric circle centered on the wafer support 300 and at least one straight line extending in the radial direction of the wafer support 300. Since the spacing of concentric circles is all the same, the lengths of straight lines may all be the same. In an embodiment, at least one of the intervals of the concentric circles may be different, so that at least one of the lengths of the straight lines may be different.

In example embodiments, the first support area Z1 may have a circular shape including the center of the wafer support 300. The second to fourth support areas Z2 to Z4 may be disposed to surround the first support area Z1, and the second to fourth support areas Z2 to Z4 may have the same shape. The fifth to seventh support areas Z5 to Z7 may be disposed to surround the second to fourth support areas Z2 to Z4, and the fifth to seventh support areas Z5 to Z7 may have the same shape. The 8th to 16th support areas Z8 to Z16 may be disposed to surround the 5th to 7th support areas Z5 to Z7, and the 8th to 16th support areas Z8 to Z16 may have the same shape.

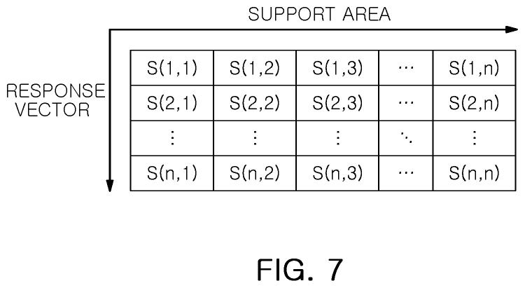

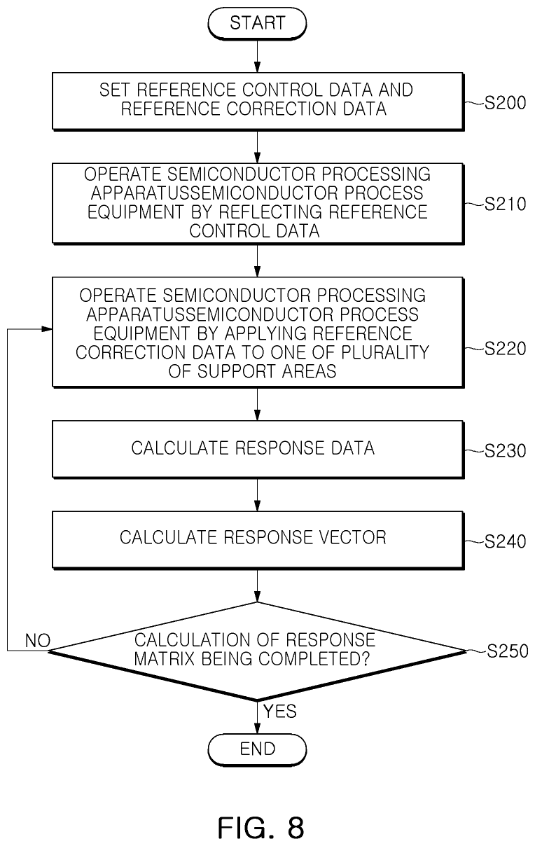

FIG. 7 is a diagram illustrating a response matrix according to example embodiments. FIG. 8 is a flowchart illustrating the process of calculating a response matrix according to example embodiments.

The processor according to example embodiments may generate correction data for each of the plurality of support areas based on the response matrix and modify the control data. Detailed embodiments thereof may be similar to those previously described in FIGS. 1 to 6.

In example embodiments, the processor may calculate representative data for each of a plurality of measurement areas from the measurement data and calculate error data by calculating a difference between the representative data and predetermined target data. For example, the representative data may be the average of measurement data obtained from each of a plurality of measurement areas. In an embodiment, in each of the plurality of measurement areas, multiple measurements may be performed at different locations, and measurement data of the multiple measurements are averaged to generate the representative data of each of the plurality of measurement areas.

The processor may modify control data for each of the plurality of support areas using the correction data. For example, the correction data may be the amount of change in control data for each of the plurality of support areas. In an embodiment, the correction data may be applied to the current control data, thereby modifying or adjusting the current control data to generate new modified control data to be applied in step S160. For example, the correction data may be obtained from measurement data resulted from a semiconductor process based on the current control data, and the correction data may be added to or subtracted from the current control data to obtain new modified control data.

The processor according to example embodiments may generate correction data based on a response matrix, and the response matrix may define the relationship between correction data and error data. In detail, the processor may generate correction data using error data.

First, referring to FIG. 7, the response matrix in an example embodiment may be an n×n matrix. In an embodiment, a column vector of the error data may be obtained by multiplying the response matrix with a column vector of the amount of change in the control data (i.e., the correction data). Rows of the response matrix may correspond to response vectors for correction data. For example, the number of rows in the column vector of the correction data may be equal to the number of the plurality of support areas, and the number of rows in the error data may be equal to the number of the plurality of measurement areas. To obtain the column vector of the control data, the inverse matrix of the response matrix may be multiplied with the column vector of the error data. Each row of the column vector of the correction data may be associated with a corresponding one the plurality of support areas. The response vector may define a relationship between reference correction data and error data for each of a plurality of measurement areas calculated by applying the reference correction data to one of the plurality of support areas. For example, the second row of the response matrix may define the relationship between reference correction data and error data calculated by applying the reference correction data to the second support area.

The component S of the response matrix may represent the relationship between reference correction data applied to one support area and error data of one measurement area. For example, component S (2,1) may represent the relationship between reference correction data applied to the first support area and error data of the second measurement area.

The number of rows of the response matrix may be equal to the number of measurement areas, and the number of columns of the response matrix may be equal to the number of support areas. In an example embodiment illustrated in FIG. 7, a plurality of measurement areas correspond to a plurality of support areas, so the number of rows (n) and the number of columns (n) of the response matrix may be the same. When a plurality of measurement areas correspond to a plurality of support areas in the embodiment illustrated in FIG. 6, the response matrix may be a 16×16 matrix. Below, the process of calculating the response matrix is explained.

Referring to FIG. 8, the processor may set reference control data and reference correction data (S200). The reference control data may be the control data which is applied to a plurality of support areas. The reference correction data corresponds to the amount of change relative to the reference control data and may be applied to at least one support area.

In the case of control data reflecting the reference correction data, modified control data to which reference correction data is applied may be reflected in one of the plurality of support areas, and the reference control data may be reflected in the remaining areas. For example, the reference control data may be applied to each of the plurality of support areas, and the reference correction data may be added to the reference control data of the one of the plurality of support areas.

For example, when the control data is the temperature for each of the plurality of support areas, the reference control data may be set to 210° C., and the reference correction data may be set to +1° C. The control data reflecting the reference correction data may have a temperature of 211° C. for at least one area and 210° C. for the remaining areas. However, the present inventive concept may not be limited thereto.

The processor may operate a semiconductor process equipment by reflecting the reference control data in the plurality of support areas (S210). The measurement apparatus may acquire measurement data from a plurality of measurement areas of the wafer on which the semiconductor process has been performed, and the processor may store the measurement data received from the measurement apparatus as reference measurement data.

The processor may operate a semiconductor process equipment by applying reference correction data to one of the plurality of support areas (S220). The measurement apparatus may acquire measurement data from a plurality of measurement areas of the wafer on which the semiconductor process has been performed, and the processor may store the measurement data received from the measurement apparatus as correction measurement data.

The processor may calculate response data by calculating the difference between the correction measurement data and the reference measurement data (S230). The processor may calculate a response vector through the relationship between the response data and the reference correction data (S240). For example, when reference correction data is applied to the second support area, the response vector of the second row of the response matrix illustrated in FIG. 7 may be calculated.

Afterwards, the processor may determine whether calculation of the response matrix has been completed (S250). When all response vectors of the response matrix have been calculated, it may be determined that the calculation of the response matrix has been completed. When the calculation of the response matrix is not completed (NO in S250), the process of calculating the response vector by applying the reference correction data may be repeated (S220 to S250).

When the calculation of the response matrix is complete (YES in S250), the process may be terminated. In example embodiments, all response vectors may be calculated by applying reference correction data to all plurality of support areas. In an embodiment, all response vectors may be calculated by applying reference correction data to some of the support areas in consideration of the symmetry of the plurality of support areas. Referring to FIG. 6 together, by applying reference correction data to the first, second, fifth, eighth, ninth, and tenth support areas Z1, Z2, Z5, Z8, Z9, and Z10, all response vectors may be calculated.

For example, the response vector calculated by applying the reference correction data to the second support area Z2 may be the same as the response vector calculated by applying the reference correction data to the third and fourth support areas Z3 and Z4. The response vector calculated by applying the reference correction data to the fifth support area Z5 may be the same as the response vector calculated by applying the reference correction data to the sixth and seventh support areas Z6 and Z7. The response vector calculated by applying the reference correction data to the eighth support area Z8 may be the same as the response vector calculated by applying the reference correction data to the 11th and 14th support areas Z11 and Z14. The response vector calculated by applying the reference correction data to the ninth support area Z9 may be the same as the response vector calculated by applying the reference correction data to the 12th and 15th support areas Z12 and Z15. The response vector calculated by applying the reference correction data to the 10th support area Z10 may be the same as the response vector calculated by applying the reference correction data to the 13th and 16th support areas Z13 and Z16.

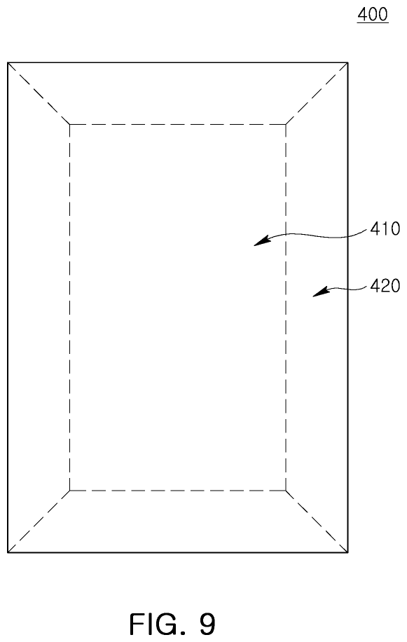

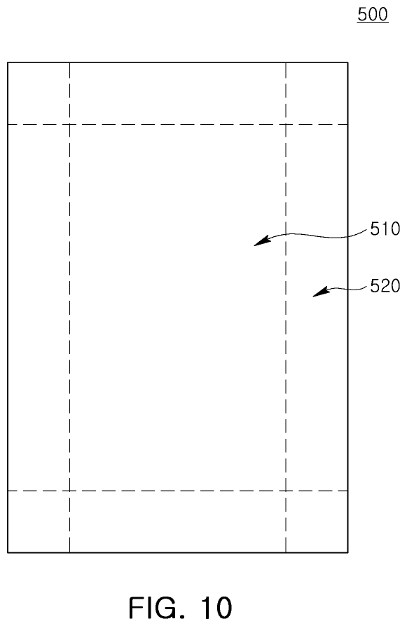

FIGS. 9 and 10 are diagrams simply illustrating a plurality of sub-areas according to example embodiments. FIG. 11 is a diagram illustrating a response matrix according to example embodiments.

In example embodiments, a measurement apparatus may acquire measurement data from a plurality of measurement areas defined on a wafer on which a semiconductor process has been performed. Detailed embodiments of a semiconductor process equipment and a measurement apparatus may be similar to those previously described in FIGS. 1 to 6.

In example embodiments, a plurality of measurement areas may correspond to a plurality of support areas. Each of the plurality of measurement areas may include a plurality of sub-areas. At least one region among the plurality of sub-areas may have a different shape and/or size. One of the plurality of sub-areas may be disposed to be surrounded by the remaining areas. However, the present inventive concept may not be limited thereto.

Referring to FIGS. 9 and 10, one measurement area 400 or 500 among a plurality of measurement areas may be simply illustrated. The measurement areas 400 and 500 may include a plurality of sub-areas 410, 420, 510, and 520. One sub-area 410 or 510 of the plurality of sub-areas may be disposed to be surrounded by the remaining sub-areas 420 or 520.

First, referring to FIG. 9, the sub-area 410 located in the center of the measurement area 400 may have a quadrangular shape. The remaining areas 420 may be divided based on the vertices of the sub-area 410 and the vertices of the measurement area 400. For example, the remaining areas 420 may be divided into four areas, and a pair of remaining areas opposing each other may have the same shape.

Referring to FIG. 10, the measurement area 500 may be divided by orthogonal straight lines. At least one of the intervals between the plurality of straight lines may be different and may have an interval of a certain ratio. For example, the intervals between a plurality of straight lines may have a ratio of 0.15:0.7:0.15, but may not be limited thereto. All of the plurality of sub-areas 510 and 520 may have a quadrangular shape. For example, the remaining sub-areas 520 may be divided into eight areas.

The response matrix of an example embodiment illustrated in FIG. 11 may be a (n*m)×n matrix. The rows of the response matrix correspond to the response vectors for the correction data, and the response vector may define the relationship between the reference correction data and the response data for each of the plurality of sub-areas calculated by applying the reference correction data to one of the plurality of sub-areas.

A component S of the response matrix may represent the relationship between reference correction data applied to one support area and error data to one sub-area. For example, component S (21,1) may represent the relationship between reference correction data applied to the first support area and error data for the first sub-area included in the second measurement area.

The number of rows of the response matrix may be equal to the number of the plurality of sub-areas, and the number of columns of the response matrix may be equal to the number of the plurality of support areas. Each of the plurality of measurement areas may include the same number of sub-areas.

In an example embodiment illustrated in FIG. 11, each of the n measurement areas may include a plurality of m sub-areas. In detail, the total number of sub-areas may be (n*m). Therefore, the number of rows (n*m) of the response matrix may be different from the number of columns (n) of the response matrix.

The response matrix of FIG. 11 may be calculated similarly to the calculation process of the embodiment illustrated in FIG. 8. At this time, the measurement apparatus may obtain measurement data from a plurality of sub-areas of the wafer where the semiconductor process has been performed. The processor may calculate response data for a plurality of sub-areas based on the measurement data received from the measurement apparatus, and calculate a response vector.

In example embodiments, the processor may calculate representative data for each of the plurality of sub-areas and calculate error data for each of the plurality of sub-areas by calculating a difference between the representative data and predetermined target data. The processor may modify the control data by generating correction data for each of the plurality of support areas based on the response matrix of FIG. 11.

Compared with the response matrix in FIG. 7, the response matrix in FIG. 11 may more accurately reflect the impact of correction data on the process results on the wafer. In detail, the response matrix of FIG. 11 may reflect the influence of correction data and process results of a plurality of sub-areas that subdivide the plurality of support areas. Accordingly, the precision of correction data generated based on the response matrix of FIG. 11 may be high.

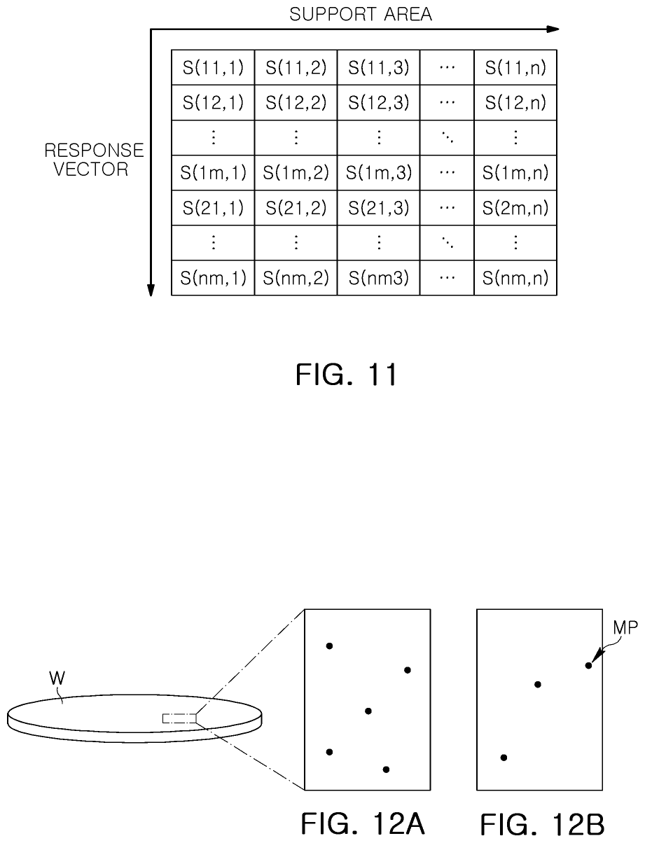

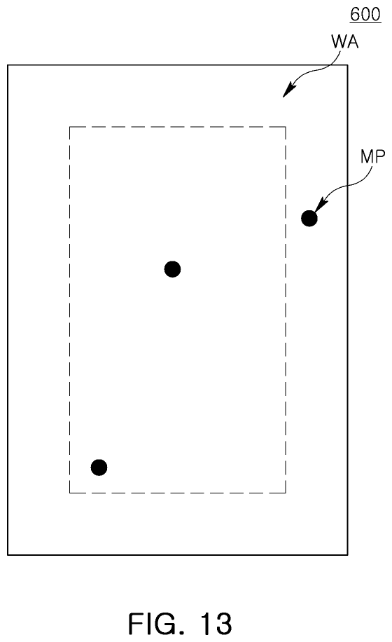

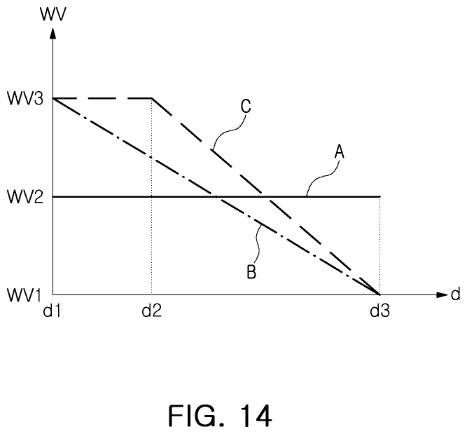

FIGS. 12A and 12B are diagrams illustrating a measurement area according to example embodiments. FIG. 13 is a diagram illustrating a measurement area according to example embodiments. FIG. 14 is a diagram illustrating weights according to example embodiments.

A semiconductor process equipment according to example embodiments may include a wafer support and a processor. The wafer support may include a plurality of support areas, and a wafer may be seated thereon. Detailed embodiments of a semiconductor process equipment and a measurement apparatus may be similar to those previously described in FIGS. 1 to 11.

A measurement apparatus may obtain measurement data from a plurality of measurement areas defined on a wafer on which a semiconductor process has been performed. The processor may calculate representative data from measurement data received from a measurement apparatus. The processor may determine final control data using representative data. Below, the measurement data and representative data will be described in detail.

First, FIGS. 12A and 12B may illustrate one measurement area among a plurality of measurement areas defined on the wafer W. The measurement apparatus may acquire measurement data by measuring at least one measurement point MP in a single measurement area. In example embodiments, representative data may be the average of measurement data obtained from a plurality of respective measurement areas.

In the measurement area of FIG. 12A, five measurement points MP may be measured to obtain measurement data, and the average of the measurement data may be representative data. In the measurement area of FIG. 12B, three measurement points MP may be measured to obtain measurement data, and the average of the measurement data may be representative data.

In an embodiment, the representative data may be a weighted average of measurement data obtained from each of a plurality of measurement areas. At least one of the plurality of measurement areas may include a weighted area. A weight value of less than 1 may be applied to measurement data acquired in a weighted area, and a weight value of 1 may be applied to measurement data acquired in a measurement area other than the weighted area. The weighted area may be a certain area adjacent to the boundary of each of the plurality of measurement areas. For example, in FIG. 9, at least one of the remaining areas 420 may correspond to the weighted areas, and in FIG. 10, at least one of the remaining sub-areas 520 may correspond to the weighted areas. However, the present inventive concept may not be limited thereto.

Referring to FIG. 13, one measurement area 600 among the plurality of measurement areas may include a weighted area WA. Weighted area WA may be part of one measurement area 600. For example, the weighted area WA may be a certain area adjacent to the boundary of each of the plurality of measurement areas.

In an example embodiment illustrated in FIG. 13, three measurement points MP may be measured in one measurement area 600 to obtain measurement data. A weight value less than 1 may be applied to the measurement data for one point located in the weighted area WA among the three points. A weight value of 1 may be applied to the measurement data for the remaining two points.

The graph illustrated in FIG. 14 may represent the weight WV according to the point d at which the measurement data was acquired. The weight WV may be constant or variable depending on the point d at which the measurement data is acquired.

Referring to FIGS. 13 and 14, the first point dl may correspond to the boundary of the weighted area WA, and the third point d3 may correspond to the boundary of one measurement area 600. In detail, FIG. 14 may represent the weight WV of the weighted area WA. The first weight WV1 may be 0, and the third weight WV3 may be 1. However, the present inventive concept may not be limited thereto.

The graph A in FIG. 14 may have a constant second weight WV in the weighted area WA, and the second weight WV may be greater than 0 and less than 1, but may not be limited thereto.

In the graph B, the closer the border of one measurement area 600 is, the smaller the weight WV may be. At this time, the change in weight WV may be in the form of a straight line, but is not limited thereto and may be in the form of a curve.

In the graph C, the weight WV is constant up to the second point d2 adjacent to the border of the weighted area WA, and the closer the second point d2 is to the boundary of the single measurement area 600, the smaller the weight WV may be.

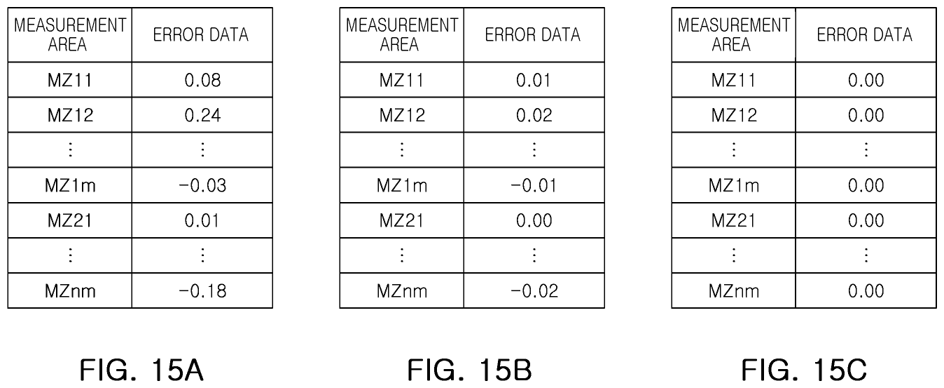

FIGS. 15A to 15C is diagrams illustrating error data calculated from a semiconductor process equipment according to example embodiments.

A semiconductor process equipment according to example embodiments may include a wafer support and a processor. A wafer may be seated on the wafer support, and the wafer support may include a plurality of support areas. The processor may receive measurement data obtained from a plurality of measurement areas defined on a wafer on which a semiconductor process has been performed, and may determine control data for each of a plurality of support areas controlling the semiconductor process.

The plurality of measurement areas in example embodiments correspond to a plurality of support areas, and each of the plurality of measurement areas may include a plurality of sub-areas. One of the plurality of sub-areas may be disposed to be surrounded by the remaining areas.

The processor calculates representative data for each of the plurality of measurement areas by performing a weighted average of the measurement data obtained from each of the plurality of measurement areas, and calculates error data by calculating the difference between the representative data and predetermined target data.

The processor may generate the correction data for each of a plurality of support areas based on a response matrix that defines a relationship between correction data and error data for modifying the control data for each of the plurality of support areas to modify the control data. The processor may determine final control data using correction data whose error data is within a predetermined target range.

Detailed embodiments of a semiconductor process equipment of the present inventive concept may be similar to those previously described in FIGS. 1 to 14.

The measurement area illustrated in FIGS. 15A to 15C may correspond to a plurality of sub-areas, and each of the n measurement areas may include a plurality of m sub-areas.

FIG. 15A may illustrate error data for each of a plurality of sub-areas calculated by reflecting control data and performing a semiconductor process. In the case in which the error data in FIG. 15A does not fall within a predetermined target range, the processor may modify the control data based on the response matrix. At this time, the response matrix of an example embodiment illustrated in FIG. 11 may be applied.

FIG. 15B may represent error data calculated by performing a semiconductor process by reflecting the control data modified in FIG. 15A. Compared to FIG. 15A, the range of error data in FIG. 15B may be smaller. In detail, the process result in FIG. 15B may be more uniform. However, in the case in which the error data in FIG. 15B does not fall within the predetermined target range, the processor may modify the control data based on the response matrix.

FIG. 15C may represent error data calculated by performing a semiconductor process by reflecting the control data modified in FIG. 15B. Compared to FIG. 15B, the range of error data in FIG. 15C may be smaller and may fall within a predetermined target range. In detail, the process result in FIG. 15C may be more uniform, and the modified control data reflected in FIG. 15C may be determined as the final control data.

As set forth above, according to example embodiments, a response matrix may reflect an influence of control data for each of a plurality of support areas on process results of each of a plurality of measurement areas. In modifying control data based on the response matrix, correction accuracy may be improved and the number of modifications may be reduced.

While example embodiments have been illustrated and described above, it will be apparent to those skilled in the art that modifications and variations could be made without departing from the scope of the present inventive concept as defined by the appended claims.

What is claimed is:

1. Semiconductor process equipment comprising:
a wafer support with a wafer seated thereon and including a plurality of support areas; and
a processor configured to:
receive measurement data obtained from a plurality of measurement areas defined on the wafer on which a semiconductor process has been performed based on current control data for each of the plurality of support areas controlling the semiconductor process;
calculate representative data for each of the plurality of measurement areas from the measurement data;
calculate error data by calculating a difference between the representative data and predetermined target data;
determine, in response to the error data falling within a predetermined range, the current control data as final control data; and
in response to the error data being out of the predetermined range, generate correction data for each of the plurality of support areas based on a response matrix defining a relationship between the correction data correcting the current control data for each of the plurality of support areas and the error data of the plurality of measurement areas and adjust the current control data with the correction data to generate a modified control data.

2. The semiconductor process equipment of claim 1,
wherein the representative data is an average of measurement data obtained from a plurality of measurement points of each of the plurality of respective measurement areas.

3. The semiconductor process equipment of claim 1,
wherein the correction data includes a change amount of the current control data for each of the plurality of support areas.

4. The semiconductor process equipment of claim 1,
wherein rows of the response matrix correspond to response vectors for the correction data.

5. The semiconductor process equipment of claim 4,
wherein the response vectors define a relationship between reference correction data and response data for each of the plurality of measurement areas,
wherein the reference correction data corresponds to an amount of change relative to reference control data which is applied to the plurality of support areas,
wherein the response data is obtained by calculating a difference between correction measurement data and reference measurement data,
wherein the reference measurement data corresponds to measurement data of the plurality of measurement areas obtained by applying the reference control data to the plurality of support areas, and
wherein the correction measurement data corresponds to measurement data of the plurality of measurement areas obtained by applying the reference correction data to one of the plurality of support areas.

6. The semiconductor process equipment of claim 4,
wherein the number of the rows of the response matrix is equal to the number of the plurality of measurement areas, and
wherein the number of columns of the response matrix is equal to the number of the plurality of support areas.

7. The semiconductor process equipment of claim 1,
wherein the plurality of measurement areas correspond to the plurality of support areas.

8. The semiconductor process equipment of claim 7,
wherein each of the plurality of measurement areas includes a plurality of sub-areas.

9. The semiconductor process equipment of claim 8,
wherein at least one sub-area among the plurality of sub-areas has a different shape.

10. The semiconductor process equipment of claim 8,
wherein one sub-area of the plurality of sub-areas is disposed to be surrounded by remaining sub-areas thereof.

11. The semiconductor process equipment of claim 8,
wherein rows of the response matrix correspond to response vectors for the correction data,
wherein the response vectors define a relationship between reference correction data and response data for each of the plurality of sub-areas,
wherein the reference correction data corresponds to an amount of change relative to reference control data which is applied to the plurality of support areas,
wherein the response data is obtained by calculating a difference between correction measurement data and reference measurement data,
wherein the reference measurement data corresponds to measurement data of the plurality of sub-areas obtained by applying the reference control data to the plurality of support areas, and
wherein the correction measurement data corresponds to measurement data of the plurality of sub-areas obtained by applying the reference correction data to one of the plurality of support areas.

12. The semiconductor process equipment of claim 11,
wherein the number of the rows of the response matrix is equal to the number of the plurality of sub-areas, and
wherein the number of columns of the response matrix is equal to the number of the plurality of support areas.

13. Semiconductor process equipment comprising:
a wafer support with a wafer seated thereon and including a plurality of support areas; and
a processor configured to:
receive measurement data obtained from a plurality of measurement areas defined on the wafer on which a semiconductor process has been performed based on current control data for each of the plurality of support areas controlling the semiconductor process;
calculate representative data for each of the plurality of measurement areas from the measurement data by calculating a weighted average of the measurement data obtained from each of the plurality of measurement areas;
calculate error data by calculating a difference between the representative data and predetermined target data;
determine, in response to the error data falling within a predetermined range, the current control data as final control data; and
in response to the error data being out of the predetermined range, generate correction data for each of the plurality of support areas based on a response matrix defining a relationship between the correction data correcting the current control data for each of the plurality of support areas and the error data of the plurality of measurement areas and adjust the current control data with the correction data to generate a modified control data.

14. The semiconductor process equipment of claim 13,
wherein the correction data includes a change amount of the current control data for each of the plurality of support areas.

15. The semiconductor process equipment of claim 13,
wherein rows of the response matrix correspond to response vectors for the correction data,
wherein the response vectors define a relationship between reference correction data and response data for each of the plurality of measurement areas,
wherein the reference correction data corresponds to an amount of change relative to reference control data which is applied to the plurality of support areas,
wherein the applying of the reference correction data includes adding of the reference correction data to the reference control data of the one of the plurality of support areas,
wherein the response data is obtained by calculating a difference between correction measurement data and reference measurement data,
wherein the reference measurement data corresponds to measurement data of the plurality of measurement areas obtained by applying the reference control data to the plurality of support areas, and
wherein the correction data corresponds to measurement data of the plurality of measurement areas obtained by applying the reference correction data to one of the plurality of support areas.

16. The semiconductor process equipment of claim 15,
wherein the number of the rows of the response matrix is equal to the number of columns of the response matrix.

17. The semiconductor process equipment of claim 13,
wherein at least one of the plurality of measurement areas includes a weighted area, and
wherein the processor applies a weight value less than 1 to measurement data obtained in the weighted area.

18. The semiconductor process equipment of claim 17,
wherein the weighted area corresponds an area adjacent to a boundary of each of the plurality of measurement areas.

19. The semiconductor process equipment of claim 17,
wherein the weight value is a variable depending on a location in which the measurement data is obtained.

20. Semiconductor process equipment comprising:
a wafer support with a wafer seated thereon and including a plurality of support areas; and
a processor configured to:
receive measurement data obtained from a plurality of measurement areas defined on the wafer on which a semiconductor process has been performed based on current control data for each of the plurality of support areas controlling the semiconductor process,
wherein the plurality of measurement areas correspond to the plurality of support areas, and each of the plurality of measurement areas includes a plurality of sub-areas, and one sub-area of the plurality of sub-areas is disposed to be surrounded by remaining sub-areas of the plurality of sub-areas;
calculate representative data for each of the plurality of measurement areas by performing a weighted average of the measurement data obtained from each of the plurality of measurement areas;
calculate error data by calculating a difference between the representative data and predetermined target data;
determine, in response to the error data falling within a predetermined range, the current control data as final control data; and
in response to the error data being out of the predetermined range, generate correction data for each of the plurality of support areas based on a response matrix defining a relationship between the correction data correcting the current control data for each of the plurality of support areas and the error data of the plurality of measurement areas and adjust the current control data with the correction data to generate a modified control data.
